(19) United States
(12) Patent Application Publication
(10) Pub. No.: US 2026/0206587 A1
(43) Pub. Date: Jul. 16, 2026

(54) COOLING DEVICE, COOLING SYSTEM AND IMMERSION COOLING SYSTEM

(71) Applicant: Infineon Technologies Austria AG, Villach (AT)

(72) Inventors: Uwe KIRCHNER, Witra (AT); Richard KNIPPER, Regensburg (DE); Julian TREU, München (DE); Anton MAUDER, Kolbermoor (DE); Andre Dominik FLECHSIG, Soest (DE); Michael STADLER, München (DE); Christian RÜTHER, Warstein-Mülheim (DE)

(21) Appl. No.: 19/418,548

(22) Filed: Dec. 12, 2025

(30) Foreign Application Priority Data
Jan. 10, 2025 (DE) 102025100704.7

(51) Int. Cl. H10W 40/30; H10W 40/20; H10W 40/47; H10W 40/50

(52) U.S. Cl. CPC H10W 40/30; H10W 40/242; H10W 40/47; H10W 40/50

(57) ABSTRACT

A cooling device for cooling a discrete semiconductor package, includes a housing, wherein the housing includes a heat exchange surface configured to match with a corresponding heat emitting surface of the semiconductor package, and wherein the housing surrounds a liquid chamber and includes distribution elements arranged to form a fluid channel for a cooling liquid through the liquid chamber between an inlet portion and an outlet portion, wherein the fluid channel is configured to guide a flow of the cooling liquid inside the housing alongside the heat exchange surface.

### CROSS-REFERENCE TO RELATED APPLICATION

This application claims priority to Germany Patent Application No. 102025100704.7 filed on Jan. 10, 2025, the content of which is incorporated by reference herein in its entirety.

### TECHNICAL FIELD

The present disclosure relates to a cooling device, a cooling system and an immersion cooling system for cooling a discrete semiconductor package. A housing of the cooling device surrounds a liquid chamber and comprises distribution elements arranged to form a fluid channel for a cooling liquid through the liquid chamber between an inlet portion and an outlet portion. The cooling system comprises a cooling device and a semiconductor package. The immersion cooling system comprises the cooling device, a semiconductor package and an immersion bath in which the semiconductor package is immersed.

### BACKGROUND

To achieve high power densities in high power applications, especially chargers and battery storage systems, the market moves to liquid cooling. Furthermore, the power demand is still increasing. Particularly for systems with high reliability requirements, a minimum of components is desired. Moreover, heatsinks have to be specifically modified for liquid cooling. This can be seen in transformers being maintenance free for up to 30 years using hermetically sealed immersion cooling.

The present disclosure relates to two aspects of shortcomings of the present liquid cooling technology. Currently, there is no adequate tradeoff between ease of manufacturing/implementation on our customer side and outstanding performance.

It is an objective of the present disclosure to at least mitigate these shortcomings.

### SUMMARY

A first aspect of the disclosure relates to a cooling device for cooling a discrete semiconductor package, the device including: a housing, wherein the housing includes a heat exchange surface configured to match with a corresponding heat emitting surface of the semiconductor package, and wherein the housing surrounds a liquid chamber and includes distribution elements arranged to form a fluid channel for a cooling liquid through the liquid chamber between an inlet portion and an outlet portion, wherein the fluid channel is configured to guide a flow of the cooling liquid inside the housing alongside the heat exchange surface.

The housing of the cooling device may be any surrounding or casing. The housing includes sidewalls, wherein at least one of the sidewalls forms or is replaced by a heat exchange surface, that is, a portion of the housing which is configured to conduct heat from an inside of the housing to an outside of the housing and vice versa.

An interior space of the housing may form the liquid chamber. The liquid chamber may be a portion which is configured to enable a liquid to be accommodated inside the housing. The liquid chamber may comprise distribution elements, that is, elements that subdivide that liquid chamber into separate portions. The separate portions may be communicatively coupled or linked to one another so as to form a fluid channel or liquid channel through the liquid chamber. The fluid channel may consist of sequentially arranged portions of the liquid chamber, linking an inlet portion to an outlet portion to enable a flow of a cooling liquid through the liquid chamber.

The cooling liquid may be an electrically isolating liquid. The cooling liquid may be any liquid which is suitable for heat transfer.

The housing of the cooling device may include or may be made from an electrical isolating material. The housing of the cooling device may include a plastic material, e.g. a thermoplastic material or a thermoset material.

The fluid channel is arranged to guide the liquid flow through the liquid chamber and past the heat exchange surface. Passing alongside the heat exchange surface coming from the inlet portion, the cooling liquid receives heat from the heat exchange surface and, by the liquid flow, transports the heat away from the heat exchange surface and thus away from the heat source.

According to the first aspect, a modular cooling solution for cooling of discrete devices is provided. The cooling device ensures creepage/clearance compliance while allowing simple integration at customer site.

The discrete device, that is the semiconductor package, may be directly coupled to the fluid channel. The electrical insulation may be done via the cooling liquid or an isolated backside of the discrete device.

According to the first aspect, a semiconductor body and a housing of the cooling device link together and may be cascaded into multi-part assemblies without increasing the connection effort for cooling liquid routing as it is internally covered whilst ensuring electrical insulation.

An effect of the first aspect of the disclosure may be an ease of manufacturing and reduced assembly complexity ensuring reliable sealing whilst keeping engineering effort low, due to cooling devices being adapted to common packages of discrete power electronic devices.

In particular, the heat emitting surface is in thermal contact with the fluid channel, particularly wherein the heat exchange surface or the corresponding heat emitting surface form a sidewall of the housing. That is, the heat emitting surface may be the heat exchange surface.

In an implementation, the housing includes an opening, the opening enabling a thermal connection between the heat emitting surface of the semiconductor package and the fluid channel. The opening may be a recess or a window-like portion. The semiconductor package may fit exactly into the opening such that a contact side of the semiconductor package may be arranged at least in part inside the housing.

Particularly, the opening is arranged at the heat exchange surface.

A pressure resistant elastic element may be arranged inside the opening, the pressure resistant element forming the heat exchange surface. Particularly, the pressure resistant elastic element is a silicone foil or a latex foil. The pressure resistant element may be stretched inside the opening, forming a stretched plane. The pressure resistant element may hence form the heat exchange surface of the housing. The pressure resistant element may also be electrically insulating.

By the elasticity the element may be pressed, by a pressure of the cooling liquid inside the liquid chamber, against a heat emitting surface of e.g., the semiconductor package. Thereby a tight thermal connection between the pressure resistant element and hence the cooling liquid and the heat emitting surface is enabled.

By the electrical insulation, the pressure resistant element may insulate the cooling liquid against the heat emitting surface of e.g., the semiconductor package, hence enabling use of a non-isolating cooling liquid, for example water or a water-glycol mixture.

In an implementation, the distribution elements are arranged so as to form a U-shaped fluid channel, wherein a flow direction of the cooling liquid through the inlet portion is substantially parallel to a flow direction of the cooling liquid through the outlet portion. In this implementation, the fluid channel forms a flow reverser, that is, a flow of the cooling liquid at the inlet portion is substantially in an opposite direction with respect to the flow of the cooling liquid at the outlet portion.

In an implementation, the housing includes a mounting portion configured to fix the semiconductor package at the housing, wherein the mounting portion includes a threaded bore to accommodate a screw. The mounting portion may be a protrusion and may be an integral part of the housing. The mounting portion may protrude vertically towards the heat exchange surface. A distal end of the mounting portion may be in contact with the heat exchange surface and may have an additional gasket, particularly an O-ring at its end face. The mounting portion may include a fixing means, particularly a thread, to accommodate a screw. According to another implementation, the housing may accommodate a receiving part for a clamping mechanism configured to fix the semiconductor package at the housing. However, other fixing means are also envisaged.

In an implementation, the housing includes at least two openings. That is, as each of the openings are configured to accommodate a backside of a semiconductor package, a plurality of semiconductor package may be cooled, that is linked to the fluid channel of one cooling device. If a device includes more than one heat exchange surfaces, a plurality of the semiconductor packages may be linked at the same device to the same or a different fluid channel. In this way, a plurality of semiconductor packages can be linked to one cooling device that is cascaded along a flow direction of the cooling liquid through the fluid channel.

In an implementation, the opening includes a frame-like recess at a circumferential periphery of the opening, wherein the frame-like recess is configured to accommodate and fit together with the semiconductor package. The frame-like recess may be formed by a step to an inside of the housing being configured to receive a corresponding peripheral portion of the semiconductor package. By the recess, in a mounting state, a semiconductor package may be held inside the opening.

Particularly, the recess includes a gasket, particularly an O-ring or an adhesive, to establish a liquid tight connection between the housing and the semiconductor package. The body of the semiconductor package and the housing are matched together, to ensure reliable sealing whilst the mold body and/or a lead frame of the discrete device itself act as part of the housing.

In a further implementation, the fluid channel is non-liquid tight, but a gap is provided between the housing and the semiconductor package to enable a leakage flow of the cooling liquid through the opening.

In this implementation the semiconductor package and the housing are fixed together, but in a non leakage-proof manner. Being non liquid-tight or non leakage-proof means, that leakage flows through the opening are enabled. A certain amount of the cooling liquid which is inserted into the housing via the inlet portion may leave the housing not via an outlet portion, but through the opening and past the semiconductor package. Thereby, heated cooling liquid which has received heat from the semiconductor package is directly jetted out of the housing and will thus not transfer heat to further downstream parts of the fluid channel and thus of the housing.

According to this implementation a cooling device is provided that effectively cools semiconductor devices by direct jetting liquid to the device and/or it heatsinks.

This implementation is particularly envisaged for application in immersion cooling systems. A directed flow of cooling liquid allows for more indicate coolers being attached to Surface Mount Device, SMD, parts without the risk of shadowing like e.g. bubble adhesion. The cooling device acts as an injection point of cold cooling liquid into a larger immersion cooling bath/cell after contact with the high-heat area (non-sealed, no return flow). This enables effective cooling of semiconductor packages with the highest power losses by direct jetting cooling liquid to the semiconductor package. The high flow rate will reduce the blow-out effect. A blow-out effect may be that local small gas bubbles stick to a surface to be cooled and decrease heat transfer.

In an implementation, the housing includes turbulator elements protruding into the fluid channel to evoke turbulences in the cooling liquid flow at a boundary layer at the heat emitting surface. Integrated turbulators increase the heat transfer by avoiding a laminar flow at a boundary layer of the heat exchange surface. The increased flow rate at the device will reduce a blow-out effect and increase the heat transfer to the liquid.

In an implementation, the outlet portion is arranged at a sidewall of the housing opposite the heat exchange surface, and the outlet portion includes a plurality of openings. In this implementation, the outlet portion is not configured to receive, for example, a tube or a connector for guiding the cooling liquid away from the cooling device. The heated cooling liquid, having received heat inside the housing is directly jetted through the plurality of openings into an immersion cooling bath, in which both the semiconductor package and the cooling device are immersed. The cooling device does not necessarily have to be sealed because it is placed in the liquid itself. There are other cooling device versions possible, like double sided, endless etc. In case of passive elements like magnetic elements which also require effective cooling, other forms of cooling devices like a bell-shaped cover or a direct jetting by a nozzle, are also envisaged.

According to a second aspect of the disclosure a cooling system is provided, the system including the cooling device of the first aspect and a semiconductor package, the semiconductor package including the heat emitting surface, wherein the heat emitting surface is configured to match with the housing, particularly with the heat exchange surface.

In an implementation of the second aspect of the disclosure, the cooling system includes one or more of
a snap-in connector forming the inlet and/or the outlet portion; a tube system for transporting the cooling liquid to the cooling device and/or away from the cooling device; a cooler, connected to the tube system and configured to remove heat from the cooling liquid; a pump for circulating the cooling liquid through the cooling device, the tube system and the cooler; a temperature sensor; a controller for controlling the flow of cooling liquid, by the pump, based on sensing data of the temperature sensor.

According to a third aspect of disclosure, an immersion cooling system is provided, the system including the cooling device according to some implementations of the first aspect; a semiconductor package, the semiconductor package including the heat emitting surface; and an immersion bath in which the semiconductor package is immersed.

Particularly the immersion bath may be an immersion cell which may be also referred to as a closed system. The system may be a passive or an active system, wherein a passive system may be referred to as a system without any means for circulating the cooling liquid. In contrast thereto, an active system may be a system including active mechanical means for circulating the cooling liquid.

In an implementation of the third aspect the immersion cooling system includes one or more of a snap-in connector forming the inlet portion; a tube system for transporting the cooling liquid to the cooling device; a cooler, connected to the tube system and configured to remove heat from the cooling liquid; a pump for circulating the cooling liquid through the cooling device, the tube system and the cooler; a temperature sensor; a controller for controlling the flow of cooling liquid, by the pump, based on sensing data of the temperature sensor.

All implementations of each aspect of the disclosure are also envisaged as implementations of all of the other aspects of the disclosure.

### BRIEF DESCRIPTION OF THE DRAWINGS

Example implementations of the disclosure are described with reference to the following figures:

FIG. 1 shows a first example implementation of the first aspect of the present disclosure.

FIG. 2 shows the implementation of FIG. 1.

FIG. 3 shows another view of the implementation of a cooling device according to FIG. 1.

FIG. 4 shows a cooling device of the second aspect of the disclosure.

FIG. 5 shows an implementation of the cooling device shown in FIG. 4.

FIG. 6 shows a closed view of a cooling device according to the present disclosure.

FIG. 7 shows an interior view of cooling device configured to be stacked together with a plurality of cooling devices according to the disclosure.

FIG. 8 shows an arrangement comprising a plurality of stacked cooling devices according to FIG. 7.

FIG. 9 shows another aspect of the cooling device of the first aspect of the disclosure.

FIG. 10 shows a cooling system.

FIG. 11 shows an immersion cooling system.

### DETAILED DESCRIPTION

In the following detailed description, reference is made to the accompanying drawings. The drawings show specific examples in which the implementation may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. A semiconductor package has electrically connected pads and includes at least one semiconductor element with electrodes. The pads are electrically connected to the electrodes which includes that the pads are the electrodes and vice versa.

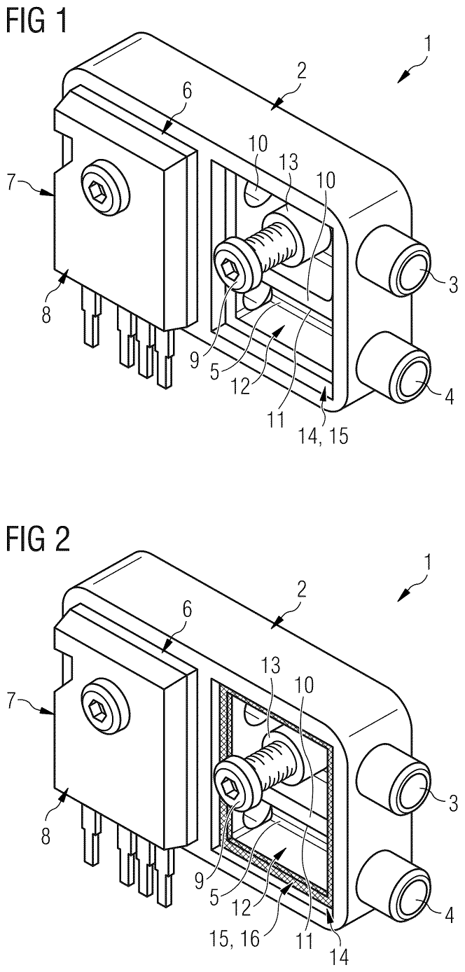

FIG. 1 shows a cooling device 1 of the first aspect of the present disclosure. The cooling device comprises a housing 2. The housing 2 is of a substantially rectangular shape. At an end face the housing 2 comprises an inlet portion 3 and an outlet portion 4. The housing 4 surrounds a liquid chamber 5. At a major sidewall of the housing 2, the housing 2 comprises at least one heat exchange surface 6.

In the description, reference is made to the accompanying figures in which the housing may comprise two or more heat exchange surfaces. Nevertheless, for ease of understanding the description may use the singular form to address features.

The heat exchange surface 6 is configured to match with a heat emitting surface 7 of a semiconductor package 8. The semiconductor package 8 is attached to the housing 2. The semiconductor package 8 is fixed by a screw 9.

The liquid chamber 5 inside the housing 2 comprises distribution elements 10. The distribution elements 10 are arranged inside the housing and subdivide the housing 2 into one or more channels for a cooling liquid, that is a fluid channel 11. The cooling liquid is guided along a pathway of the fluid channel 11 from the inlet portion 3 to the outlet portion 4. The fluid channel 11 guides the cooling liquid past the heat exchange surface 6.

The heat emitting surface 7 is in thermal contact with the fluid channel 11. The heat emitting surface 7 forms a sidewall of the housing 2. In this implementation the heat emitting surface 7 corresponds to the heat exchange surface 6.

To get the heat emitting surface 7 of the semiconductor package 8 in contact with the fluid channel 11, the housing 2 comprises an opening 12. The opening 12 is arranged at the heat exchange surface 6 of the housing 2. The semiconductor package 8 is fitted at least in part into the opening 12, that is, for example the backside of the semiconductor package 8, which may be an exposed die pad or a thermally conducting interface material, may be arranged adjacent to the liquid chamber 5.

Distribution elements 10 are arranged to subdivide the liquid chamber 5 into two or more sub-chambers for each semiconductor package 8. Distribution elements 10 may include flanges, openings, bridges, or bars forming subdivisions of the liquid chamber 5. The distribution elements 10 form one or more U-shaped fluid channels, that is a flow reverser. Additionally, or alternatively to the distribution elements 10, turbulator elements (not shown in FIG. 1) may be formed in the liquid chamber 5 to avoid laminar liquid flow and enhance the heat exchange at the heat exchange surface of the housing 6.

To receive the screw 9, wherein the screw is to fix the semiconductor package 8 at the housing 2, the housing comprises a mounting portion 13. Mounting portion 13 is a cylindrical protrusion having a longitudinal axis which is substantially normal to a plane of the heat exchange surface 6. An end face of the cylindrical protrusion may be coplanar and/or located in the plane of the heat exchange surface 6. The mounting portion may comprise a bore having a threaded inlet.

The opening 12 comprises or is surrounded by a frame-like recess 14, that is a stepped portion in circumferential sidewall of the housing adjacent to the heat exchange surface 6. The frame-like recess 14 is configured to fit together with a housing or a mold body of the semiconductor package 8.

By virtue of the stepped portion, the mold body of the semiconductor package 8 extends into the housing 2 by penetrating an envelope surface of the housing 2. Between the mold body of the semiconductor package 8 and the housing 2, by the stepped portion, a labyrinth is provided, contributing to sealing the liquid chamber 5 against the outside world.

The frame-like recess may comprise a gasket 15, which may be an O-ring, a profile gasket or a lip seal. A part of the gasket 15 or another gasket may be also placed at or in the mounting portion 13. The mounting portion 13 may be equipped with a recess to accommodate this gasket.

FIG. 2 shows the implementation of FIG. 1, wherein the gasket 15 is not an O-ring, but an adhesive 16. Adhesive 16 takes the place of the O-ring of FIG. 1. The adhesive 16 may be isolating and configured to establish a leak-proof connection between the mold body of the semiconductor package 8 and the housing 2. The adhesive 16 may be also applied to the mounting portion 13 (not shown in FIG. 2).

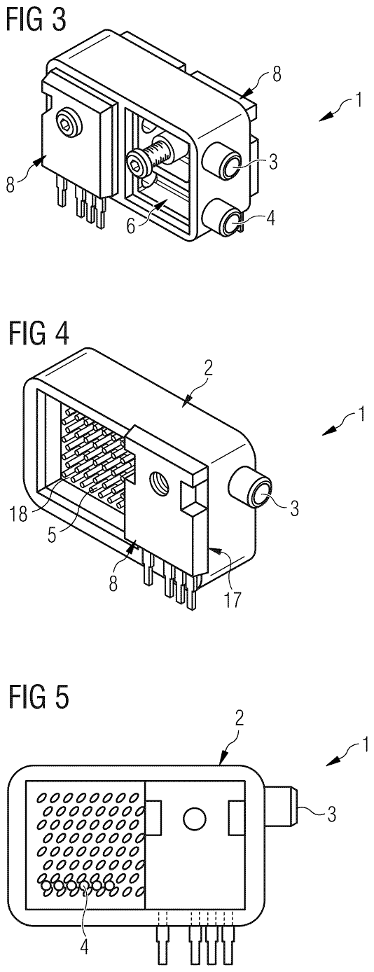

FIG. 3 shows another implementation of a cooling device 1. FIG. 3 is showing an example of a cooling device 1 suitable for more than two semiconductor packages 8 next to one another. In this implementation, the housing comprises more than one heat exchange surface 6. A second heat exchange surface is arranged opposite to the heat exchange surface 6 and adapted to accommodate semiconductor packages 8 in the same manner as the heat exchange surface 6.

FIG. 4 shows a cooling device of the second aspect of the disclosure. In this implementation the fluid channel 5 is non-liquid tight. A gap 17 may be provided between the mold body of the semiconductor device 8 and the housing 2. Through the gap 17, a leakage flow of the cooling liquid may be possible, that is the leakage flow of the cooling liquid may exit the housing 2 through the opening 12 and not through the outlet portion 4. Inlet portion 3 is provided at an end face of the housing 2.

Further, the housing 2 comprises turbulator elements 18. Turbulator elements 18 protrude into the fluid channel 5. Turbulator elements 18 are configured to evoke turbulences, at least at a boundary layer of the heat exchange surface 6 and the cooling liquid flowing past the heat exchange surface 6. By the turbulences, the Reynolds number is increased which enhances heat transfer from the heat exchange server 6 to the cooling liquid.

FIG. 5 shows an implementation of the cooling device shown in FIG. 4. The housing 2 comprises the outlet portion 4, wherein the outlet portion is arranged at the sidewall of the housing 2. The outlet portion 4 is formed by at least one opening in a surface of the sidewall of the housing 2 opposite the heat exchange surface 6. Hence, the cooling liquid enters the housing 2 at the inlet portion 3 and exits the housing 2 after having passed the heat exchange surface 6, through the openings 4. In this implementation the housing may be part of an immersion cooling system, wherein the cooling liquid is dispensed through the openings into an immersion cooling bath (not shown).

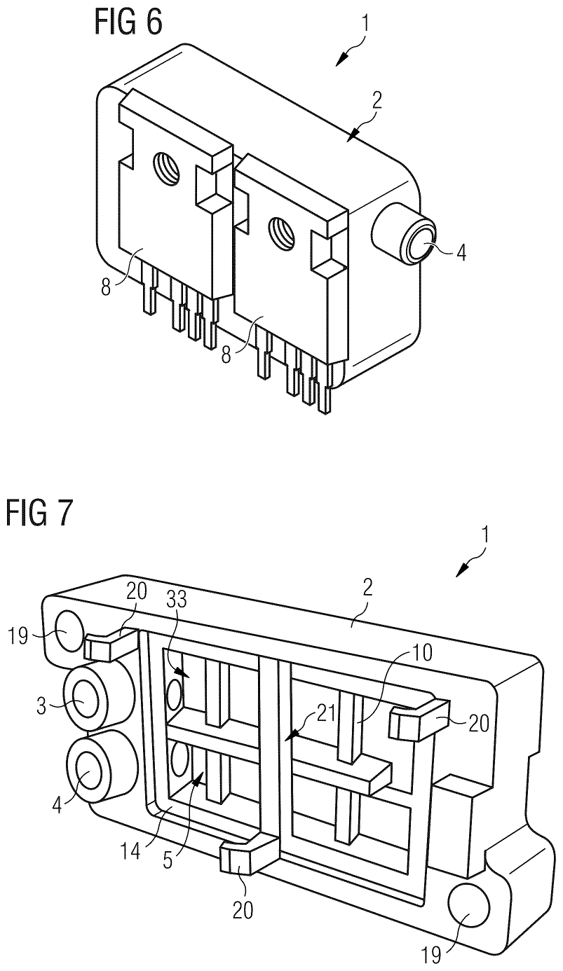

FIG. 6 shows a closed view of a cooling device 1 according to FIG. 5. The housing 2 is closed with two semiconductor packages 8 being attached to the heat exchange surfaces 6.

FIG. 7 shows an interior view of a cooling device 1 configured to be stacked together with a plurality of cooling devices 1 according to the disclosure. The housing 2 comprises attachment portions 19, which may be flanges comprising through holes. Moreover, the housing 2 comprises snap-in connectors 20. The snap in connectors 20 may be arranged such that they positively interlock, in a mounting position, that is in as state where a plurality of cooling devices is stacked together, with respective interlocking features at the respective subsequent housing 2. For stabilization, the housing further comprises a central flange 21. Inlet portion 3 may have a different diameter than outlet portion 4 for hydraulic balancing between the cooling devices 1.

A flow limiting element 33 may be placed between the inlet portion 3 and/or the outlet portion 4 of the liquid chamber 5. The flow limiting elements may be configured to enable substantially the same fluid flow rate through each stacked cooling device 1 up to a limited, predefined number of stacked cooling devices in case of continuous inlet portion 3 and outlet portion 4 forming a common rail for supplying cool liquid and returning hot liquid.

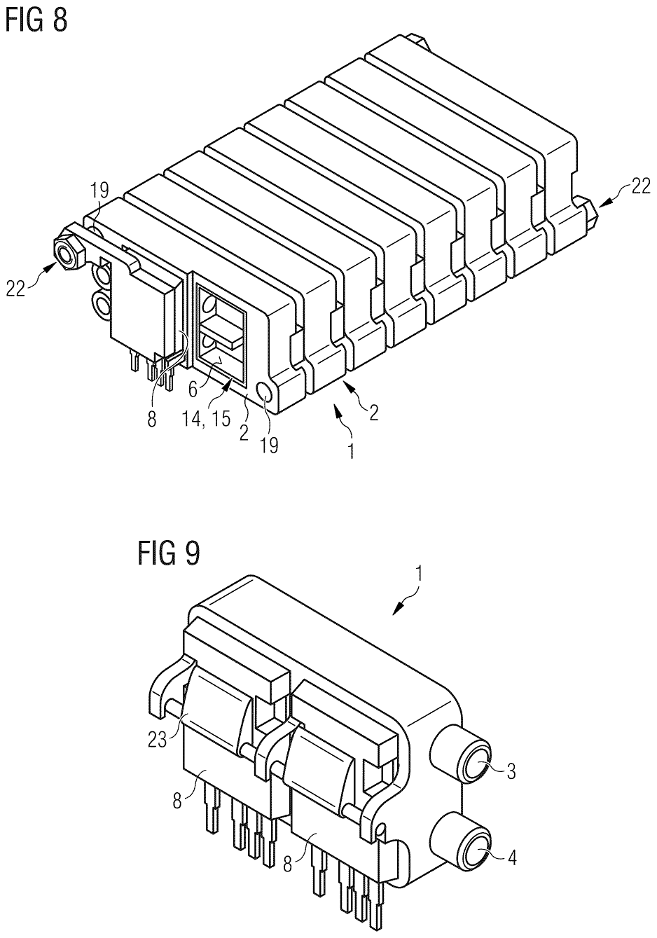

FIG. 8 shows an arrangement comprising a plurality of stacked cooling devices 1 according to FIG. 7. The cooling devices 1 of FIG. 7 are arranged in the mounting position, that is, stacked together. Semiconductor packages 8 are mounted in between the housings 2. In the stacked arrangement semiconductor packages 8 may be pressed into the frame-like recesses 14 and against the gasket 15 via the respective subsequent housing 2. That is, the semiconductor packages 8 are sandwiched in between the housings 2 and are pressed together by a suitable connector 22, which may be inserted through the attachment portions 19 and which may be configured to press each of the housings 2 against one another.

Here as many cooling devices 1 can be cascaded, either in linked-chain configuration or via shared inlet flow (flow through all cells, or flow into each cell via common rail and exit in each device).

FIG. 9 shows another aspect of the cooling device of the first aspect of the disclosure. The cooling device 1 can be connected to the semiconductor package 8 using a clamp 23 or by sliding it on the semiconductor package 8, fixed e.g. using retainer taps.

In the implementation where the cooling device 1 is used in an immersion cooling bath, there is no need for a liquid-tight connection. That is, some tolerances and leaking gaps between the cooling device 1 and the semiconductor package 8 are permissible or may even serve as the hot liquid outlet. In this case, the clamps 23 may be low-cost clamps since there is no need for exact pressure distribution. In case of sliding the cooling device 1 on the semiconductor package 8, tolerances for both sliding rails and retainers allow mechanical clearance between cooling device 1 and semiconductor package 8.

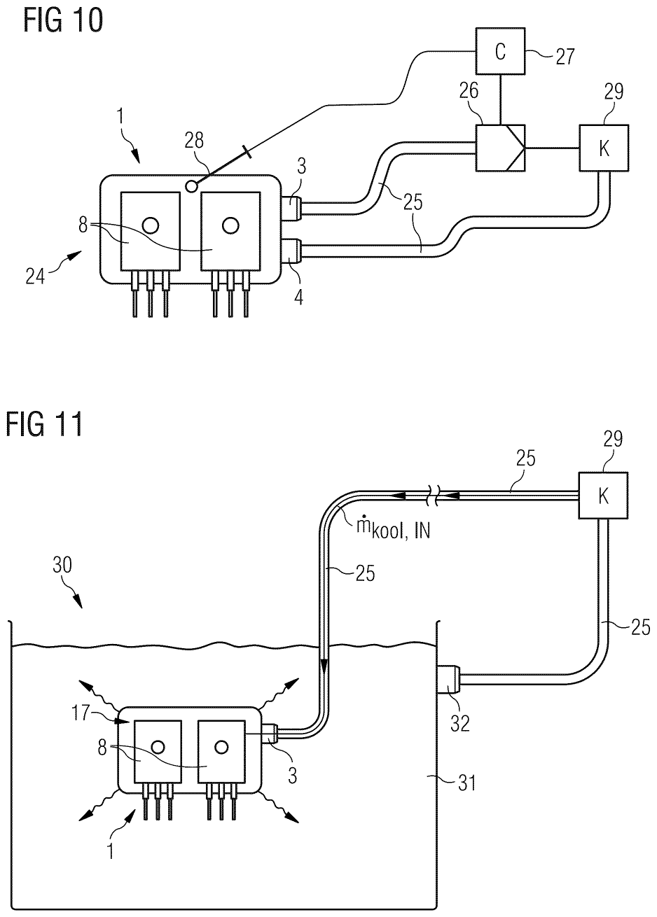

FIG. 10 shows a cooling system 24. The cooling system 24 comprises a cooling device 1, for example, according to the first aspect of the present disclosure. The cooling system 24 further comprises the semiconductor packages 8. The cooling device 1 is connected to a tube system 25 by the inlet portion 3 and the outlet portion 4. Both the inlet portion 3 and the outlet portion 4 may be formed by a snap-in connector.

The cooling system 24 may be a passive system: the cooling device 1 is not supplied via a pump but instead uses heat generated in the semiconductor parts to drive the flow of cooling liquid via a thermally driven static pressure difference. Here, the system acts like a snorkel, allowing to pull cooling liquid out of low temperature areas of the cooling volume. In this way, temperatures in the media can be equalized horizontally and over larger distances than would be possible by thermally driven flow alone.

The cooling system 24 may be an active system. Therein, the cooling system 24 further comprises a pump 26 for circulating the cooling liquid true the cooling device and the tube system 25. The cooling system may further comprise a controller 27 a temperature sensor 28 and cooler 29.

FIG. 11 shows an immersion cooling system 30. The immersion cooling system 30 comprises an immersion bath 31 in which the cooling device 1 according to the second aspect of the disclosure is immersed. Semiconductor packages 8 are also immersed in the immersion bath 31 and attached to the cooling device 1 according to the second aspect of disclosure. The cooling device 1 is again connected to a tube system 25, however only one connector to the tube system 25 is present, namely the inlet portion 3. The immersion cooling system 30 may be equipped with a pump for circulating the liquid or it may use convection. A cooler 29 may be connected to the immersion cooling system 30. The cooling device 1 serves as distribution element for pre-cooled cooling liquid, wherein the pre-cooled cooling liquid is exactly led to the point of the highest thermal load, which may be the semiconductor packages 8. Through the gap 17 leakage flows of the cooling liquid may flow into the immersion bath 31. The immersion bath 31 has an outlet 32, which may guide heated cooling liquid to a further cooling system, e.g., a cooler. As such, the immersion cooling bath 31 together with the immersed cooling device 1 according to the second aspect of disclosure, may also be part of cooling system 24 according to FIG. 10.

Since the cooling device 1 in the immersion cooling bath 31 allows a focused cooling of hot spots like power semiconductors, high flow rates of the liquids occur only where they are needed, i.e. the total flow rate of the liquid of the whole appliance can be reduced compared to conventional immersion cooling. Other components with lower heat dissipation like passives or conductors can be cooled depending on their maximum allowed temperature either by the heated return flow coming from the adapter outlets or some bypass openings of cool liquid. Since the density of power loss of these components is significantly lower, either hotter income liquid and/or lower flow rates are acceptable.

The cooling devices 1 according to the second aspect of the disclosure which are deployed in an immersion cooling environment reduce cooling effort by directing a stream of cooling media from a cold area (reservoir, heat exchanger etc.) directly into the highest temperature area of the cooling media pool. This way, cooling of hot-spots can be done on minimum bath temperature instead of average bath temperature. To keep engineering effort low, the cell will not feature a return line but will be built as open system. This way, each device doubles as injection point for cold media into the bath. Here, the liquid is already at elevated temperatures and leaves the device through an outlet system, flowing into the overall volume of immersion cooling liquid.

### ASPECTS

The following provides an overview of some Aspect s of the present disclosure:

Aspect 1: A cooling device for cooling a discrete semiconductor package, the cooling device comprising: a housing, wherein the housing comprises a heat exchange surface configured to match with a corresponding heat emitting surface of the discrete semiconductor package, wherein the housing surrounds a liquid chamber and comprises distribution elements arranged to form a fluid channel for a cooling liquid through the liquid chamber between an inlet portion and an outlet portion, and wherein the fluid channel is configured to guide a flow of the cooling liquid inside the housing alongside the heat exchange surface.

Aspect 2: The cooling device of Aspect 1, wherein the heat emitting surface is in thermal contact with the fluid channel, particularly wherein the heat exchange surface or the corresponding heat emitting surface form a sidewall of the housing.

Aspect 3: The cooling device of any of Aspects 1-2, wherein the housing comprises an opening, the opening enabling a thermal connection between the heat emitting surface of the discrete semiconductor package and the fluid channel.

Aspect 4: The cooling device of Aspect 3, wherein the opening is arranged at the heat exchange surface, and wherein a pressure resistant elastic element is arranged inside the opening, the pressure resistant elastic element forming the heat exchange surface, particularly wherein the pressure resistant elastic element is a silicone foil or a latex foil.

Aspect 5: The cooling device of any of Aspects 1-4, wherein the distribution elements are arranged so as to form a U-shaped fluid channel, wherein a flow direction of the cooling liquid through the inlet portion is substantially parallel to a flow direction of the cooling liquid through the outlet portion.

Aspect 6: The cooling device of any of Aspects 1-5, wherein the housing comprises a mounting portion configured to fix the discrete semiconductor package at the housing, wherein the mounting portion comprises a threaded bore to accommodate a screw.

Aspect 7: The cooling device of Aspect 3, wherein the housing comprises at least two openings.

Aspect 8: The cooling device of Aspect 4, wherein the opening comprises a frame-like recess at a circumferential periphery of the opening, and wherein the frame-like recess is configured to accommodate and fit together with the discrete semiconductor package.

Aspect 9: The cooling device of Aspect 8, wherein the frame-like recess comprises a gasket, particularly an O-ring or an adhesive, to establish a liquid tight connection between the housing and the discrete semiconductor package.

Aspect 10: The cooling device of Aspect 3, wherein the fluid channel is non-liquid tight, but wherein a gap is provided between the housing and the discrete semiconductor package to enable a leakage flow of the cooling liquid through the opening.

Aspect 11: The cooling device of any of Aspects 1-10, wherein the housing comprises turbulator elements protruding into the fluid channel to evoke turbulences in the flow of the cooling liquid at a boundary layer at the heat emitting surface.

Aspect 12: The cooling device of any of Aspects 1-11, wherein the outlet portion is arranged at a sidewall of the housing opposite the heat exchange surface, and wherein the outlet portion comprises a plurality of openings.

Aspect 13: A cooling system comprising cooling device for cooling a semiconductor package, the cooling device comprising: a housing, wherein the housing comprises a heat exchange surface configured to match with a corresponding heat emitting surface of the semiconductor package, wherein the housing surrounds a liquid chamber and comprises distribution elements arranged to form a fluid channel for a cooling liquid through the liquid chamber between an inlet portion and an outlet portion, and wherein the fluid channel is configured to guide a flow of the cooling liquid inside the housing alongside the heat exchange surface; and the semiconductor package, the semiconductor package comprising the heat emitting surface, wherein the heat emitting surface is configured to match with the housing, particularly with the heat exchange surface.

Aspect 14: The cooling system of Aspect 13, further comprising: a snap-in connector forming the inlet portion and/or the outlet portion; a tube system for transporting the cooling liquid to the cooling device and/or away from the cooling device; a cooler, connected to the tube system and configured to remove heat from the cooling liquid; a pump for circulating the cooling liquid through the cooling device, the tube system and the cooler; a temperature sensor; and a controller for controlling the flow of the cooling liquid, by the pump, based on sensing data of the temperature sensor.

Aspect 15: An immersion cooling system comprising: cooling device for cooling a semiconductor package, the cooling device comprising: a housing, wherein the housing comprises a heat exchange surface configured to match with a corresponding heat emitting surface of the semiconductor package, wherein the housing surrounds a liquid chamber and comprises distribution elements arranged to form a fluid channel for a cooling liquid through the liquid chamber between an inlet portion and an outlet portion, wherein the fluid channel is configured to guide a flow of the cooling liquid inside the housing alongside the heat exchange surface, wherein the fluid channel is non-liquid tight, and wherein a gap is provided between the housing and the semiconductor package to enable a leakage flow of the cooling liquid through an opening of the housing; and the semiconductor package, the semiconductor package comprising the heat emitting surface; and an immersion bath in which the semiconductor package is immersed.

Aspect 16: The immersion cooling system of Aspect 15, further comprising: a snap-in connector forming the inlet portion; a tube system for transporting the cooling liquid to the cooling device; a cooler, connected to the tube system and configured to remove heat from the cooling liquid; a pump for circulating the cooling liquid through the cooling device, the tube system and the cooler; a temperature sensor; and a controller for controlling the flow of cooling liquid, by the pump, based on sensing data of the temperature sensor.

Aspect 17: A system configured to perform one or more operations recited in one or more of Aspects 1-16.

Aspect 18: An apparatus comprising means for performing one or more operations recited in one or more of Aspects 1-16.

### LIST OF REFERENCE SIGNS

1. Cooling device
2. Housing
3. inlet portion
4. outlet portion
5. liquid chamber
6. heat exchange surface
7. heat emitting surface
8. Semiconductor package
9. Screw
10. distribution elements
11. fluid/fluid channel
12. opening
13. mounting portion
14. frame-like recess
15. gasket/O-ring
16. adhesive
17. gap
18. turbulator elements
19. attachment portion
20. snap in connectors
21. central flange
22. connector
23. clamp
24. cooling system
25. tube system
26. pump
27. controller
28. temperature sensor
29. cooler (K)
30. immersion cooling system
31. immersion bath
32. outlet
33. flow limiting element

1. A cooling device for cooling a discrete semiconductor package, the cooling device comprising:
a housing,
wherein the housing comprises a heat exchange surface configured to match with a corresponding heat emitting surface of the discrete semiconductor package,
wherein the housing surrounds a liquid chamber and comprises distribution elements arranged to form a fluid channel for a cooling liquid through the liquid chamber between an inlet portion and an outlet portion, and
wherein the fluid channel is configured to guide a flow of the cooling liquid inside the housing alongside the heat exchange surface.

2. The cooling device of claim 1, wherein the heat emitting surface is in thermal contact with the fluid channel, particularly wherein the heat exchange surface or the corresponding heat emitting surface form a sidewall of the housing.

3. The cooling device of claim 1, wherein the housing comprises an opening, the opening enabling a thermal connection between the heat emitting surface of the discrete semiconductor package and the fluid channel.

4. The cooling device of claim 3, wherein the opening is arranged at the heat exchange surface, and wherein a pressure resistant elastic element is arranged inside the opening, the pressure resistant elastic element forming the heat exchange surface, particularly wherein the pressure resistant elastic element is a silicone foil or a latex foil.

5. The cooling device of claim 1, wherein the distribution elements are arranged so as to form a U-shaped fluid channel, wherein a flow direction of the cooling liquid through the inlet portion is substantially parallel to a flow direction of the cooling liquid through the outlet portion.

6. The cooling device of claim 1, wherein the housing comprises a mounting portion configured to fix the discrete semiconductor package at the housing, wherein the mounting portion comprises a threaded bore to accommodate a screw.

7. The cooling device of claim 3, wherein the housing comprises at least two openings.

8. The cooling device of claim 4, wherein the opening comprises a frame-like recess at a circumferential periphery of the opening, and
wherein the frame-like recess is configured to accommodate and fit together with the discrete semiconductor package.

9. The cooling device of claim 8, wherein the frame-like recess comprises a gasket, particularly an O-ring or an adhesive, to establish a liquid tight connection between the housing and the discrete semiconductor package.

10. The cooling device of claim 3, wherein the fluid channel is non-liquid tight, but wherein a gap is provided between the housing and the discrete semiconductor package to enable a leakage flow of the cooling liquid through the opening.

11. The cooling device of claim 1, wherein the housing comprises turbulator elements protruding into the fluid channel to evoke turbulences in the flow of the cooling liquid at a boundary layer at the heat emitting surface.

12. The cooling device of claim 1, wherein the outlet portion is arranged at a sidewall of the housing opposite the heat exchange surface, and wherein the outlet portion comprises a plurality of openings.

13. A cooling system comprising
cooling device for cooling a semiconductor package, the cooling device comprising:
a housing,
wherein the housing comprises a heat exchange surface configured to match with a corresponding heat emitting surface of the semiconductor package,
wherein the housing surrounds a liquid chamber and comprises distribution elements arranged to form a fluid channel for a cooling liquid through the liquid chamber between an inlet portion and an outlet portion, and
wherein the fluid channel is configured to guide a flow of the cooling liquid inside the housing alongside the heat exchange surface; and
the semiconductor package, the semiconductor package comprising the heat emitting surface, wherein the heat emitting surface is configured to match with the housing, particularly with the heat exchange surface.

14. The cooling system of claim 13, further comprising:
a snap-in connector forming the inlet portion and/or the outlet portion;
a tube system for transporting the cooling liquid to the cooling device and/or away from the cooling device;
a cooler, connected to the tube system and configured to remove heat from the cooling liquid;
a pump for circulating the cooling liquid through the cooling device, the tube system and the cooler;
a temperature sensor; and
a controller for controlling the flow of the cooling liquid, by the pump, based on sensing data of the temperature sensor.

15. An immersion cooling system comprising:
cooling device for cooling a semiconductor package, the cooling device comprising:
a housing,
wherein the housing comprises a heat exchange surface configured to match with a corresponding heat emitting surface of the semiconductor package,
wherein the housing surrounds a liquid chamber and comprises distribution elements arranged to form a fluid channel for a cooling liquid through the liquid chamber between an inlet portion and an outlet portion,
wherein the fluid channel is configured to guide a flow of the cooling liquid inside the housing alongside the heat exchange surface,
wherein the fluid channel is non-liquid tight, and
wherein a gap is provided between the housing and the semiconductor package to enable a leakage flow of the cooling liquid through an opening of the housing; and
the semiconductor package, the semiconductor package comprising the heat emitting surface; and
an immersion bath in which the semiconductor package is immersed.

16. The immersion cooling system of claim 15, further comprising:
a snap-in connector forming the inlet portion;
a tube system for transporting the cooling liquid to the cooling device;
a cooler, connected to the tube system and configured to remove heat from the cooling liquid;
a pump for circulating the cooling liquid through the cooling device, the tube system and the cooler;
a temperature sensor; and
a controller for controlling the flow of cooling liquid, by the pump, based on sensing data of the temperature sensor.
